(19) United States
(12) Patent Application Publication
(10) Pub. No.: US 2026/0164731 A1
(43) Pub. Date: Jun. 11, 2026

(54) NITRIDE SEMICONDUCTOR DEVICE

(71) Applicant: Panasonic Intellectual Property Management Co., Ltd., Osaka (JP)

(72) Inventors: Hideyuki OKITA, Osaka (JP); Masahiro HIKITA, Hyogo (JP); Kazuki TATEOKA, Kyoto (JP); Daisuke MASUNAGA, Osaka (JP)

(21) Appl. No.: 19/150,147

(22) PCT Filed: Feb. 21, 2024
(86) PCT No.: PCT/JP2024/006385

§ 371 Date: Jul. 22, 2025

(30) Foreign Application Priority Data
Mar. 27, 2023 (JP) 2023-049253

(51) Int. Cl. H10D 62/10; H10D 30/47; H10D 62/60

(52) U.S. Cl. CPC H10D 62/102; H10D 30/475; H10D 62/60; H10D 30/476

(57) ABSTRACT

A nitride semiconductor device includes: a substrate; a first nitride semiconductor layer disposed above the substrate; a second nitride semiconductor layer that is in contact with a top of the first nitride semiconductor layer and has a bandgap larger than a bandgap of the first nitride semiconductor layer; a gate layer that is selectively disposed on the second nitride semiconductor layer and includes a p-type nitride semiconductor; a drain layer that is spaced apart from the gate layer and includes a p-type nitride semiconductor; and a drain electrode that is electrically connected to both the second nitride semiconductor layer and the drain layer, the second nitride semiconductor layer includes a region that is doped with an n-type impurity, and an end portion of the region on a gate side is located between the gate layer and the drain layer, the region being doped with the n-type impurity.

### TECHNICAL FIELD

The present disclosure relates to the structure of a semiconductor device, particularly to a semiconductor which can be used as a field effect transistor or the like, and particularly to a device which uses a Group III nitride semiconductor.

### BACKGROUND ART

A Group III nitride semiconductor has a high dielectric breakdown voltage due to its wide bandgap. It is possible to easily form a heterostructure such as AlGaN/GaN, and a piezoelectric charge generated by a difference in lattice constant between AlGaN and GaN and a difference in bandgap can generate a high mobility and high concentration electron channel (two-dimensional electron gas) on the side of a GaN layer at an AlGaN/GaN interface. The two-dimensional electron gas is controlled, and thus a high electron mobility transistor (HEMT) can be formed. Due to these characteristics of high voltage resistance, high speed, and large current, the Group III nitride semiconductor has been applied to electronic devices such as field effect transistors (FETs) and diodes for power applications.

In a semiconductor device shown in FIG. 1 in Patent Literature 1 (PTL 1), an n-type nitride semiconductor layer is formed between a p-type nitride semiconductor layer on a drain side and a first nitride semiconductor layer. According to PTL 1, the n-type nitride semiconductor layer is formed below the p-type nitride semiconductor layer, and thus it is possible to suppress the spread of the depletion layer of the p-type nitride semiconductor layer and to suppress a decrease in the concentration of a two-dimensional electron gas, with the result that it is said that while current collapse is being suppressed, even when a drain voltage is low, the on-resistance of a field effect transistor can be reduced.

### CITATION

### Patent Literature

[PTL 1] Japanese Patent No. 5903642

### SUMMARY OF INVENTION

However, in a structure disclosed in PTL 1, the n-type nitride semiconductor layer is not formed at an end of the p-type nitride semiconductor layer on a gate side, with the p-type nitride semiconductor layer on the drain side where an electric field strength is higher. Hence, an electric field between the gate and the drain is not sufficiently relaxed, and thus there is still room for reduction in gate leakage current.

Hence, a nitride semiconductor device according to an aspect of the present disclosure includes: a substrate; a first nitride semiconductor layer disposed above the substrate; a second nitride semiconductor layer that is in contact with a top of the first nitride semiconductor layer and has a bandgap larger than a bandgap of the first nitride semiconductor layer; a gate layer that is selectively disposed on the second nitride semiconductor layer and includes a p-type nitride semiconductor; a drain layer that is spaced apart from the gate layer and includes a p-type nitride semiconductor; and a drain electrode that is electrically connected to both the second nitride semiconductor layer and the drain layer, the second nitride semiconductor layer includes a region that is doped with an n-type impurity, and an end portion of the region on a gate side is located between the gate layer and the drain layer, the region being doped with the n-type impurity.

In the semiconductor device according to the present disclosure, it is possible to increase a drain current, and to reduce an on-resistance and a gate leakage current.

### BRIEF DESCRIPTION OF DRAWINGS

FIG. 1 is a cross-sectional view showing a cross-sectional structure of a nitride semiconductor device according to an embodiment.

FIG. 2 is a cross-sectional view showing a cross-sectional structure of a nitride semiconductor device according to a first variation of the embodiment.

FIG. 3 is a cross-sectional view showing a cross-sectional structure of a nitride semiconductor device according to a second variation of the embodiment.

FIG. 4 is a cross-sectional view showing a cross-sectional structure of a nitride semiconductor device according to a third variation of the embodiment.

FIG. 5 is a cross-sectional view showing a cross-sectional structure of a nitride semiconductor device according to a fourth variation of the embodiment.

FIG. 6 is a cross-sectional view showing a cross-sectional structure of a nitride semiconductor device according to a fifth variation of the embodiment.

FIG. 7 is a cross-sectional view showing a cross-sectional structure of a nitride semiconductor device according to a sixth variation of the embodiment.

FIG. 8 is a cross-sectional view showing a cross-sectional structure of a nitride semiconductor device according to a seventh variation of the embodiment.

FIG. 9 is a cross-sectional view showing a cross-sectional structure of a nitride semiconductor device according to an eighth variation of the embodiment.

FIG. 10 is a cross-sectional view showing a cross-sectional structure of a nitride semiconductor device according to a ninth variation of the embodiment.

FIG. 11 is a cross-sectional view showing a cross-sectional structure of a nitride semiconductor device according to a tenth variation of the embodiment.

FIG. 12 is a cross-sectional view showing a cross-sectional structure of a nitride semiconductor device according to an eleventh variation of the embodiment.

FIG. 13 is a cross-sectional view showing a cross-sectional structure of a nitride semiconductor device according to a twelfth variation of the embodiment.

FIG. 14 is a cross-sectional view showing a cross-sectional structure of a nitride semiconductor device according to another example of the twelfth variation of the embodiment.

FIG. 15 is a cross-sectional view showing a cross-sectional structure of a nitride semiconductor device according to a thirteenth variation of the embodiment.

FIG. 16 is a cross-sectional view showing a cross-sectional structure of the nitride semiconductor device according to the embodiment.

FIG. 17 is a graph showing the maximum electric field strength of a gate layer and a drain layer of a nitride semiconductor device according to sixteenth and seventeenth variations of the embodiment.

FIG. 18A is a cross-sectional view showing a cross-sectional structure in a step in a method for manufacturing the nitride semiconductor device according to the embodiment.

FIG. 18B is a cross-sectional view showing a cross-sectional structure in a step in the method for manufacturing the nitride semiconductor device according to the embodiment.

FIG. 18C is a cross-sectional view showing a cross-sectional structure in a step in the method for manufacturing the nitride semiconductor device according to the embodiment.

FIG. 18D is a cross-sectional view showing a cross-sectional structure in a step in the method for manufacturing the nitride semiconductor device according to the embodiment.

FIG. 18E is a cross-sectional view showing a cross-sectional structure in a step in the method for manufacturing the nitride semiconductor device according to the embodiment.

FIG. 18F is a cross-sectional view showing a cross-sectional structure in a step in the method for manufacturing the nitride semiconductor device according to the embodiment.

FIG. 19A is a cross-sectional view showing a cross-sectional structure in a step in another example of the method for manufacturing the nitride semiconductor device according to the embodiment.

FIG. 19B is a cross-sectional view showing a cross-sectional structure in a step in the other example of the method for manufacturing the nitride semiconductor device according to the embodiment.

FIG. 19C is a cross-sectional view showing a cross-sectional structure in a step in the other example of the method for manufacturing the nitride semiconductor device according to the embodiment.

FIG. 19D is a cross-sectional view showing a cross-sectional structure in a step in the other example of the method for manufacturing the nitride semiconductor device according to the embodiment.

FIG. 19E is a cross-sectional view showing a cross-sectional structure in a step in the other example of the method for manufacturing the nitride semiconductor device according to the embodiment.

FIG. 19F is a cross-sectional view showing a cross-sectional structure in a step in the other example of the method for manufacturing the nitride semiconductor device according to the embodiment.

### DESCRIPTION OF EMBODIMENTS

A nitride semiconductor device according to an embodiment will be specifically described below with reference to drawings. The embodiment described below indicates a specific example of the present disclosure. Numerical values, shapes, materials, constituent elements, the arrangement and connection of the constituent elements, and the like shown in the following embodiment are examples, and are not intended to limit the present disclosure. Among the constituent elements in the following embodiment, constituent elements which are not recited in the independent claim are described as optional constituent elements.

The drawings are schematic views, and are not exactly shown. Hence, for example, scales and the like in the drawings are not necessarily the same. In the drawings, substantially the same configurations are identified with the same reference signs, and repeated description is omitted or simplified.

In the present specification, terms which indicate relationships between elements, shapes of the elements, and ranges of numerical values are expressions which not only indicate exact meanings but also indicate substantially equivalent ranges such as a range including about a several percent difference.

In the present specification, terms “above” and “below” do not indicate an upward direction (vertically upward) and a downward direction (vertically downward) in absolute spatial recognition but are used as terms which are defined by a relative positional relationship based on the order of layers stacked in a multilayer configuration. The terms “above” and “below” are applied not only to a case where two constituent elements are spaced with another constituent element present between the two constituent elements but also to a case where two constituent elements are arranged in contact with each other.

In the present specification, unless otherwise specified, ordinal numbers such as “first” and “second” do not mean the number or order of constituent elements but are used to avoid confusion of similar constituent elements and distinguish between the similar constituent elements.

### Embodiment

FIG. 1 shows a cross-sectional structural view of a nitride semiconductor device according to an embodiment in which an end portion of a region doped with an n-type impurity on a gate side is located between a gate layer and a drain layer.

The nitride semiconductor device shown in FIG. 1 includes appropriate buffer layer 2 (for example, a single layer or a plurality of layers of Group III nitride semiconductors such as GaN, AlGaN, AlN, InGaN, InN, and AlInGaN) provided on appropriate Si substrate 1 (other examples include substrates of sapphire, SiC, GaN, AIN, and the like). The nitride semiconductor device includes first nitride semiconductor layer 3 (other examples include Group III nitride semiconductors of InGaN, InN, AlGaN, AlInGaN, and the like) including GaN provided on buffer layer 2. The nitride semiconductor device includes second nitride semiconductor layer 4 (for example, a single layer or a plurality of layers of Group III nitride semiconductors such as GaN, InGaN, AlN, and AlInGaN) including AlGaN provided on first nitride semiconductor layer 3. Second nitride semiconductor layer 4 has a bandgap larger than that of first nitride semiconductor layer 3, and is in direct contact with first nitride semiconductor layer 3. When second nitride semiconductor layer 4 includes AlGaN, and first nitride semiconductor layer 3 includes GaN, a piezoelectric charge generated by a difference in lattice constant between AlGaN and GaN and a difference in bandgap can generate a high concentration of two-dimensional electron gas 5 on the side of first nitride semiconductor layer 3 (channel layer) in the vicinity of an interface between second nitride semiconductor layer 4 and first nitride semiconductor layer 3.

On second nitride semiconductor layer 4, gate layer 6 (other examples include Group III nitride semiconductors of p-InGaN, p-InN, p-AlGaN, p-AlInGaN, and the like) and drain layer 7 (other examples include Group III nitride semiconductors of p-InGaN, p-InN, p-AlGaN, p-AlInGaN, and the like) which include p-GaN containing a p-type impurity (such as Mg, Zn, or C) and are selectively formed are spaced apart from each other. The concentration of the p-type impurity of gate layer 6 and drain layer 7 is preferably higher than or equal to 1E19 cm⁻³, and more preferably higher than or equal to 5E19 cm⁻³ if possible in order to cause the layers to be p-type. When a normally-off operation which will be described later in the description of the operation of the present structure is performed, as shown in FIG. 16, gate recess 15 may be provided in second nitride semiconductor layer 4 immediately below gate layer 6. Here, “Ek (k is an integer)” represents a power of 10. In other words, Ek represents 10^{k}. For example, 1E19 represents 1×10¹⁹, and 5E19 represents 5×10¹⁹. This is also true for FIG. 17 which will be described later.

On second nitride semiconductor layer 4, as in third nitride semiconductor layer 17 shown in FIG. 16, a single nitride semiconductor layer or a plurality of nitride semiconductor layers may be provided. The nitride semiconductor layer on second nitride semiconductor layer 4 has a bandgap larger than that of first nitride semiconductor layer 3, and is in direct contact with second nitride semiconductor layer 4. In an interface with second nitride semiconductor layer 4 immediately below the nitride semiconductor layer, it is desirable to prevent a two-dimensional electron gas or a two-dimensional hole gas from being formed because when a field effect transistor is formed, this may cause gate leakage. Hence, it is desirable that the bandgap of the nitride semiconductor layer be equivalent in size to or slightly smaller than that of second nitride semiconductor layer 4. When the nitride semiconductor layer includes, for example, AlGaN, its band gap is slightly smaller than that of second nitride semiconductor layer 4, and thus an Al composition is lowered, and crystallinity is improved.

Second nitride semiconductor layer 4 includes region 8 which is doped with an n-type impurity. In region 8 doped with the n-type impurity, Si (or Ge or the like) which is an n-type impurity is added by ion implantation or the like.

The n-type impurity implanted into region 8 doped with the n-type impurity has two purposes: one purpose of obtaining a low-resistant n-type nitride semiconductor layer; and the other purpose of reducing the electric field strength of gate layer 6 and drain layer 7, with the result that it is necessary to carefully set an ion implantation concentration. Specifically, the concentration of the n-type impurity in region 8 is at least higher than or equal to 1E18 cm⁻³, and preferably higher than or equal to 3E18 cm⁻³ if possible. The concentration of the n-type impurity in region 8 is preferably lower than or equal to 1E21 cm⁻³ such that the ion-implanted crystal is prevented from having a completely amorphous structure due to ion implantation damage. Region 8 doped with the n-type impurity is defined as a region in which the concentration of the n-type impurity is higher than or equal to 1E17 cm⁻³.

On second nitride semiconductor layer 4, source electrode 10 is present on a side opposite to drain layer 7 relative to gate layer 6, and is spaced apart from gate layer 6, and drain electrode 11 is present on the side of drain layer 7 relative to gate layer 6. As shown in FIG. 1, drain electrode 11 may be in direct contact with drain layer 7, or may be spaced apart from drain layer 7 (not shown). Each of source electrode 10 and drain electrode 11 includes an electrode formed of one or a combination of two or more of metals such as Ti, Al, Mo, and Hf which are in ohmic contact with the nitride semiconductor layer, and is electrically connected to two-dimensional electron gas 5. Drain electrode 11 is also electrically connected to drain layer 7.

On gate layer 6, gate electrode 9 is provided. Gate electrode 9 may be an electrode formed of one or a combination of two or more of metals such as Ti, Ni, Pd, Pt, Au, W, WSi, Ta, TIN, Al, Mo, Hf and Zr. Gate electrode 9 may be in ohmic contact with or in Schottky contact with gate layer 6. Since ohmic contact is more reliable for the gate electrode, it is desirable to use an electrode formed of one or a combination of two or more of metals such as Ni, Pt, Pd, Au, Ti, Cr, In, Sn, and Al which have low contact resistance.

The structure shown in FIG. 1 (and FIG. 16) is characterized in that the end portion of region 8 doped with the n-type impurity on the side of gate layer 6 is located between gate layer 6 and drain layer 7.

An operation when the present structure includes gate recess 15 (FIG. 16) will be described. In a state where no voltage is applied to the electrode, gate layer 6 is a p-type nitride semiconductor layer. Due to the structure of gate recess 15, gate layer 6 is physically close to two-dimensional electron gas 5, and thus two-dimensional electron gas 5 immediately below gate layer 6 is depleted by a p-n junction (off state). Even when in this state, a positive voltage is applied to drain electrode 11, and source electrode 10 is grounded, no current flows between drain electrode 11 and source electrode 10. Then, when a positive voltage is applied to gate layer 6, the p-n junction is pulled toward the side of gate electrode 9, and thus the depletion layer is reduced in size, with the result that two-dimensional electron gas 5 is generated immediately below gate layer 6 (on state). When in this state, a positive voltage is applied to drain electrode 11, and source electrode 10 is grounded, a current flows between drain electrode 11 and source electrode 10.

Although a depletion layer formed by a p-n junction is present immediately below drain layer 7, gate recess 15 is not present immediately below drain layer 7, and thus two-dimensional electron gas 5 cannot be completely depleted, with the result that a carrier concentration is low. Hence, in an on state, a current flows between drain electrode 11 and source electrode 10.

An effect of the present structure will be described. The present structure is characterized in that the end portion of region 8 doped with the n-type impurity on the gate side is located between gate layer 6 and drain layer 7. In this way, the electric field strength of the end of drain layer 7 on the gate side is changed, and thus it is possible to lower the maximum electric field strength between the gate and the drain, with the result that it is possible to reduce a gate leakage current. The concentration of two-dimensional electron gas 5 immediately below region 8 doped with the n-type impurity between the gate and the drain is increased, and thus sheet resistance is reduced, with the result that it is possible to reduce the on-resistance and to increase the maximum drain current.

Variations of the embodiment will be described below. A plurality of variations described below may be combined as necessary as long as they do not contradict each other. In other words, an aspect which is realized by a combination of the following variations is also realized as an aspect of the nitride semiconductor device of the present disclosure.

### (First Variation)

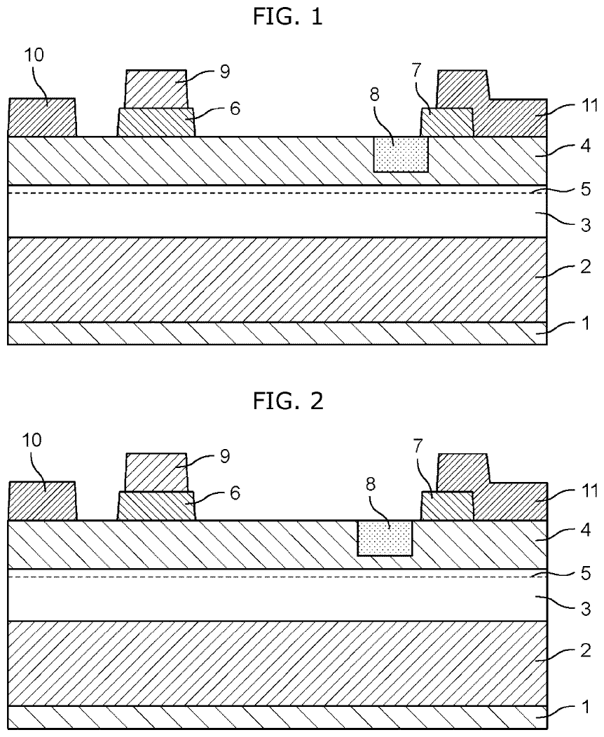

Then, FIG. 2 shows a cross-sectional structural view of a nitride semiconductor device according to a first variation of the embodiment in which an end portion of the region doped with the n-type impurity on a side opposite to the side of the gate layer is located between the gate layer and the drain layer. In FIG. 2, the end of region 8 doped with the n-type impurity on the side of drain layer 7 is spaced apart from drain layer 7 to be located between gate layer 6 and drain layer 7.

In the present variation, in addition to the effect of the embodiment, the electric field strength of the end of drain layer 7 on the side of gate layer 6 is more changed, and thus it is possible to lower the maximum electric field strength between the gate and the drain, with the result that it is possible to reduce the gate leakage current.

(Second variation)

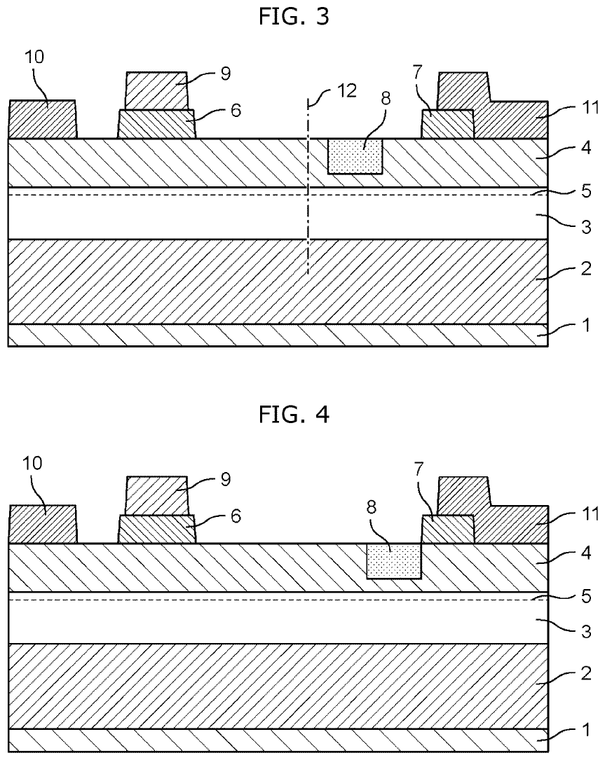

Then, FIG. 3 shows a cross-sectional structural view of a nitride semiconductor device according to a second variation of the embodiment in which the region doped with the n-type impurity is located on the side of the drain layer relative to the intermediate line of the gate layer and the drain layer. In FIG. 3, region 8 doped with the n-type impurity is located on the side of drain layer 7 relative to the intermediate line of drain layer 7 and gate layer 6.

In the present variation, in addition to the effects of the embodiment and the first variation, the depletion layer of gate layer 6 extends in the direction of drain layer 7 due to a high electric field, and thus a distance over which region 8 doped with the n-type impurity is reached is physically increased, with the result that high voltage resistance can be ensured.

### (Third Variation)

Then, FIG. 4 shows a cross-sectional structural view of a nitride semiconductor device according to a third variation of the embodiment in which the region doped with the n-type impurity is in contact with an end of the drain layer. In FIG. 4, region 8 doped with the n-type impurity is in contact with the end of drain layer 7 on the side of gate layer 6.

In the present variation, in addition to the effects of the embodiment and the first and second variations, the electric field strength of the end of drain layer 7 on the side of gate layer 6 is directly changed, and thus it is possible to lower the maximum electric field strength between the gate and the drain, with the result that it is possible to reduce the gate leakage current.

### (Fourth Variation)

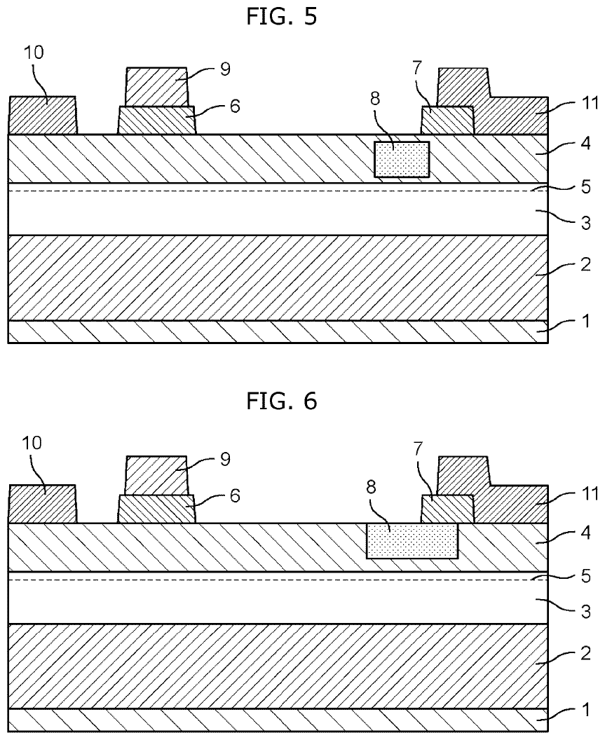

Then, FIGS. 1 to 4 show a cross-sectional structural view of a nitride semiconductor device according to a fourth variation of the embodiment in which the region doped with the n-type impurity is in the outmost surface of the second nitride semiconductor layer. In FIGS. 1 to 4, region 8 doped with the n-type impurity is in the outmost surface of second nitride semiconductor layer 4. In another variation, as shown in FIG. 5, region 8 doped with the n-type impurity may be spaced apart from the outmost surface of second nitride semiconductor layer 4.

In the present variation, in addition to the effects of the embodiment and the first to third variations, the electric field strength of the end of drain layer 7 on the gate side where the electric field is concentrated is more directly changed, and thus it is possible to lower the maximum electric field strength between the gate and the drain, with the result that it is possible to reduce the gate leakage current.

### (Fifth Variation)

Then, FIG. 6 shows a cross-sectional structural view of a nitride semiconductor device according to a fifth variation of the embodiment in which the region doped with the n-type impurity is continuous with below the drain layer. In FIG. 6, the end of region 8 doped with the n-type impurity on the side of gate layer 6 is located between gate layer 6 and drain layer 7, and the end on the side of drain layer 7 is continuous with below drain layer 7.

In the present variation, in addition to the effects of the embodiment and the second to fourth variations, region 8 doped with the n-type impurity reaches an area below drain layer 7, and thus it is possible to suppress the spread of the depletion layer immediately below drain layer 7 and to suppress a decrease in the concentration of two-dimensional electron gas 5. Hence, sheet resistance immediately below drain layer 7 is reduced, with the result that it is possible to further reduce the on-resistance and to increase the maximum drain current.

### (Sixth Variation)

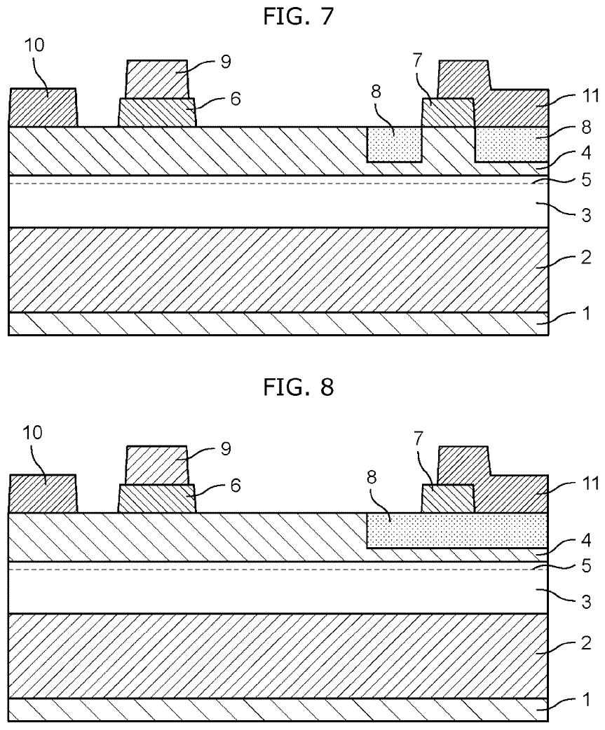

Then, FIG. 7 shows a cross-sectional structural view of a nitride semiconductor device according to a sixth variation of the embodiment in which the region doped with the n-type impurity is also present below the drain electrode. In FIG. 7, region 8 doped with the n-type impurity is present between gate layer 6 and drain layer 7, and is also present immediately below drain electrode 11.

In the present variation, in addition to the effects of the embodiment and the first to fifth variations, region 8 doped with the n-type impurity is present immediately below drain electrode 11, and thus it is possible to reduce contact resistance between drain electrode 11 and second nitride semiconductor layer 4 including region 8 doped with the n-type impurity, with the result that it is possible to further reduce the on-resistance and to increase the

### (Seventh Variation)

Then, FIG. 8 shows a cross-sectional structural view of a nitride semiconductor device according to a seventh variation of the embodiment in which the region doped with the n-type impurity is continuous with below the drain layer and with below the drain electrode. In FIG. 8, the end of region 8 doped with the n-type impurity on the side of gate layer 6 is located between gate layer 6 and drain layer 7, and the end on the side of drain layer 7 is continuous from below drain layer 7 to below drain electrode 11.

In the present variation, in addition to the effects of the embodiment and the second to sixth variations, region 8 doped with the n-type impurity is continuous with below drain layer 7 and with below drain electrode 11, and thus an n-type layer immediately below drain layer 7 pushes the p-n junction upward, and thus the number of electrons supplied to two-dimensional electron gas 5 is increased, with the result that it is possible to increase the concentration of two-dimensional electron gas 5 immediately below drain layer 7. It is also possible to reduce contact resistance between drain electrode 11 and second nitride semiconductor layer 4 including region 8 doped with the n-type impurity. In this way, it is possible to further reduce the on-resistance and to increase the maximum drain current.

### (Eighth Variation)

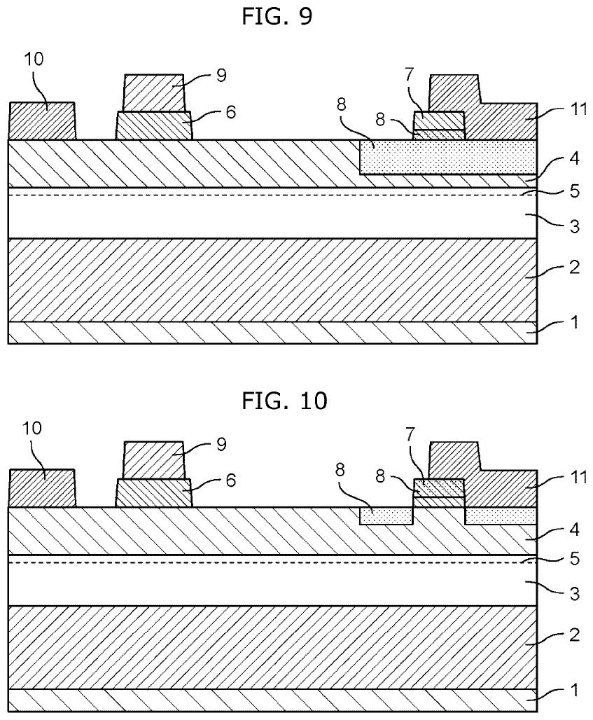

Then, FIG. 9 shows a cross-sectional structural view of a nitride semiconductor device according to an eighth variation of the embodiment in which the region doped with the n-type impurity is also present in the drain layer. In FIG. 9, region 8 doped with the n-type impurity is also present in drain layer 7. In FIG. 9, region 8 doped with the n-type impurity in drain layer 7 is shaded with overlapping diagonal lines and dots. The same is true in FIG. 10.

In the present variation, in addition to the effects of the embodiment and the first to seventh variations, region 8 doped with the n-type impurity is also present in drain layer 7, and thus an n-type layer in drain layer 7 further pushes the p-n junction upward, and thus the concentration of two-dimensional electron gas 5 immediately below drain layer 7 can be increased. In this way, it is possible to further reduce the on-resistance and to increase the maximum drain current.

### (Ninth Variation)

Then, FIG. 10 shows a cross-sectional structural view of a nitride semiconductor device according to a ninth variation of the embodiment in which the region doped with the n-type impurity is also present in the surface of the drain layer. In FIG. 10, region 8 doped with the n-type impurity is also present in the surface of drain layer 7.

In the present variation, in addition to the effects of the embodiment and the first to eighth variations, region 8 doped with the n-type impurity is present in the surface of drain layer 7, and thus a p-type region in drain layer 7 is relatively reduced, the p-n junction is pushed upward, and thus the concentration of two-dimensional electron gas 5 immediately below drain layer 7 can be increased. In this way, it is possible to further reduce the on-resistance and to increase the maximum drain current.

### (Tenth Variation)

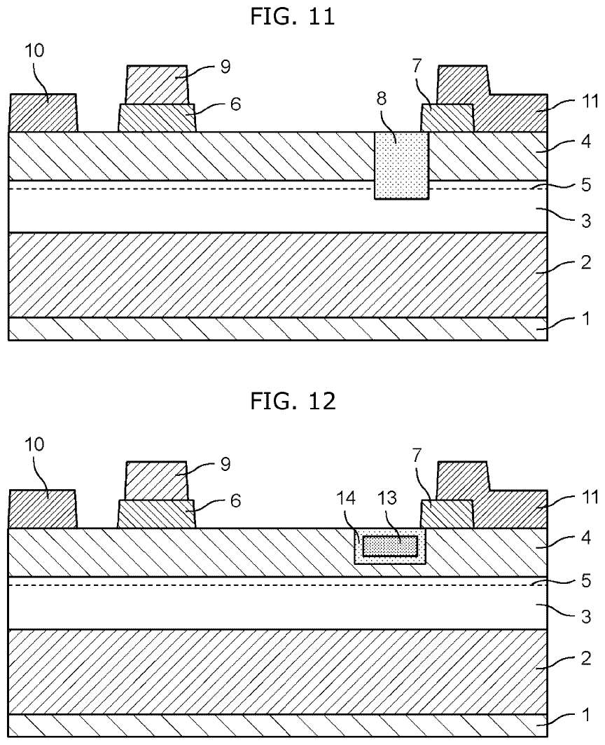

Then, FIG. 11 shows a cross-sectional structural view of a nitride semiconductor device according to a tenth variation of the embodiment in which the region doped with the n-type impurity reaches the first nitride semiconductor layer in a depth direction. In FIG. 11, region 8 doped with the n-type impurity reaches first nitride semiconductor layer 3 in the depth direction.

In the present variation, in addition to the effects of the embodiment and the first to ninth variations, region 8 doped with the n-type impurity reaches first nitride semiconductor layer 3 in the depth direction, and thus the number of electrons supplied to two-dimensional electron gas 5 is directly increased, with the result that it is possible to further reduce the on-resistance and to increase the maximum drain current.

### (Eleventh Variation)

Then, FIG. 12 shows a cross-sectional structural view of a nitride semiconductor device according to an eleventh variation of the embodiment in which the region doped with the n-type impurity includes a damaged region in a center of the region doped with the n-type impurity and a diffusion region around the damaged region, and the concentration of the n-type impurity in the diffusion region is lower than the concentration of the n-type impurity in the damaged region. In FIG. 12, the region doped with the n-type impurity includes damaged region 13 and diffusion region 14 therearound.

In the present variation, in addition to the effects of the embodiment and the first to tenth variations, crystal damage caused by ion implantation or the like does not enter diffusion region 14, and thus a higher activation rate of the n-type impurity can be obtained, with the result that it is possible to more efficiently achieve n-type conversion. In this way, the number of electrons supplied to two-dimensional electron gas 5 can be increased more efficiently, and thus it is possible to further reduce the on-resistance and to increase the maximum drain current.

### (Twelfth Variation)

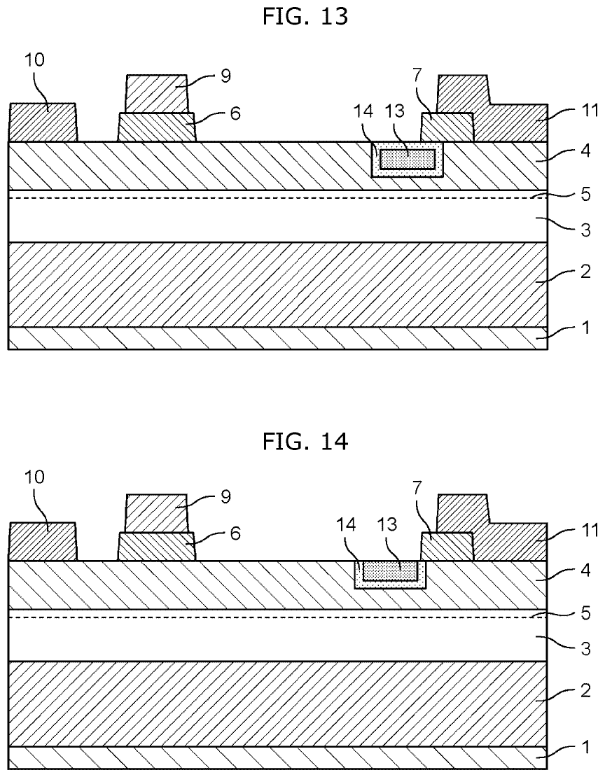

Then, FIGS. 13 and 14 show a cross-sectional structural view of a nitride semiconductor device according to a twelfth variation of the embodiment in which the region doped with the n-type impurity includes a damaged region in a center of the region doped with the n-type impurity and a diffusion region around the damaged region, and the diffusion region is present below the drain layer. In each of FIGS. 13 and 14, the region doped with the n-type impurity includes damaged region 13 and diffusion region 14 therearound. In FIG. 13, diffusion region 14 is present below drain layer 7. In FIG. 14 (also in FIG. 12), diffusion region 14 is present below drain layer 7, but damaged region 13 is not present below drain layer 7. In FIG. 14, damaged region 13 is present in the outermost surface of second nitride semiconductor layer 4.

In the present variation, in addition to the effects of the embodiment and the first to eleventh variations, crystal damage caused by ion implantation or the like does not enter diffusion region 14, and thus it is possible to suppress a trap caused by a crystal defect at the end of drain layer 7 on the side of gate layer 6 where a high electric field is applied, and to suppress the so-called current collapse phenomenon in which the drain current is reduced at high voltage.

### (Thirteenth Variation)

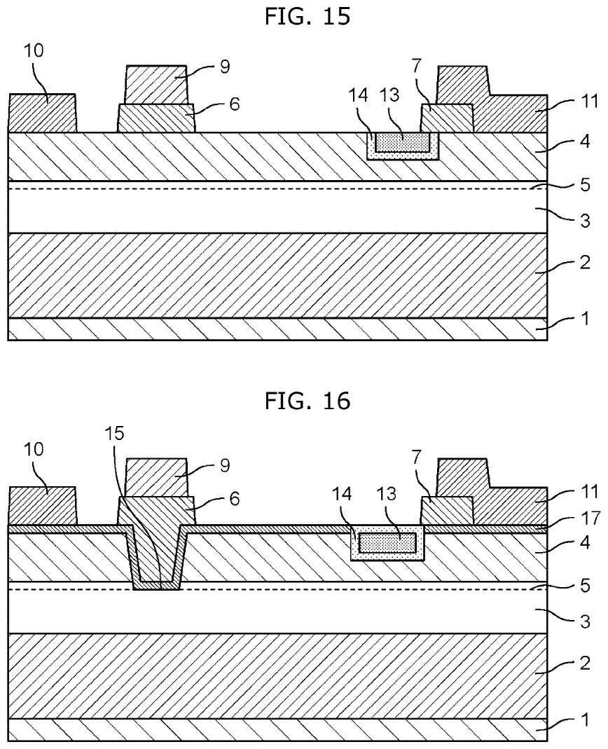

Then, FIG. 15 shows a cross-sectional structural view of a nitride semiconductor device according to a thirteenth variation of the embodiment in which the region doped with the n-type impurity includes a damaged region in a center of the region doped with the n-type impurity and a diffusion region around the damaged region, and the damaged region is present below the drain layer. In FIG. 15, the region doped with the n-type impurity includes damaged region 13 and diffusion region 14 therearound, and damaged region 13 is present below drain layer 7. In FIG. 15, damaged region 13 is present in the outermost surface of second nitride semiconductor layer 4.

In the present variation, in addition to the effects of the embodiment and the first to twelfth variations, damaged region 13 has a higher concentration of the n-type impurity than diffusion region 14. In this way, the n-type layer immediately below drain layer 7 pushes the p-n junction upward more efficiently, and thus the number of electrons supplied to two-dimensional electron gas 5 is increased, with the result that it is possible to increase the concentration of two-dimensional electron gas 5 immediately below drain layer 7, to reduce the on-resistance, and to increase the maximum drain current.

### (Fourteenth Variation)

Then, a description will be given of a nitride semiconductor device according to a fourteenth variation of the embodiment in which the region doped with the n-type impurity is within a range of 1 μm or less from an end portion of the drain layer on the side of the gate layer toward the side of the gate layer. In the present variation, region 8 doped with the n-type impurity is within a range of 1 μm or less from the end portion of drain layer 7 on the side of gate layer 6 toward the side of gate layer 6 (see, for example, FIG. 1 and the like).

In the present variation, in addition to the effects of the embodiment and the first to thirteenth variations, the end portion of region 8 doped with the n-type impurity on the side of gate layer 6 is spaced apart from gate layer 6, and thus high voltage resistance between the gate and the drain can be achieved. By contrast, when the end portion of region 8 doped with the n-type impurity on the side of gate layer 6 is close to gate layer 6, voltage resistance cannot be sufficiently ensured.

### (Fifteenth Variation)

Then, a description will be given of a nitride semiconductor device according to a fifteenth variation of the embodiment in which an end portion of the region doped with the n-type impurity on a side opposite to the gate side is within a range of 1 μm or less from an end of the drain layer on the gate side toward the side of the gate layer. In the present variation, the end portion of region 8 doped with the n-type impurity on the side opposite to gate layer 6 is within a range of 1 μm or less from the end portion of drain layer 7 on the side of gate layer 6 toward the side of gate layer 6 (see, for example, FIG. 2 and the like).

In the present variation, in addition to the effects of the embodiment and the first to fourteenth variations, region 8 doped with the n-type impurity is close to drain layer 7, and thus it is possible to more effectively reduce an electric field at the end portion of drain layer 7 on the side of gate layer 6 and an electric field at the end portion of gate layer 6 on the side of drain layer 7. In this way, high voltage resistance between the gate and the drain can be achieved.

### (Sixteenth Variation)

Then, a description will be given of a nitride semiconductor device according to a sixteenth variation of the embodiment in which the concentration of the n-type impurity in the region doped with the n-type impurity is higher than or equal to 3E18 cm⁻³. In the present variation, the concentration of the n-type impurity in region 8 doped with the n-type impurity is higher than or equal to 3E18 cm⁻³ (see, for example, FIG. 4 and the like).

FIG. 17 shows results of an electric field simulation in the present variation. The figure shows results obtained by simulating the maximum electric field at the end portion of gate layer 6 on the side of drain layer 7 and at the end portion of drain layer 7 on the side of gate layer 6 with the assumption that the width of region 8 doped with the n-type impurity in a gate-to-drain direction was fixed at 0.5 μm, the end portion of region 8 doped with the n-type impurity on the side of gate layer 6 was located 0.5 μm from the end portion of drain layer 7 on the side of gate layer 6, a drain voltage was 650 V, a gate voltage was 0 V, and a source voltage was 0 V. The thickness of region 8 doped with the n-type impurity was calculated to be three levels of 20 nm, 30 nm, and 40 nm from the surface of second nitride semiconductor layer 4, and the concentration of the impurity in region 8 doped with the n-type impurity was calculated to be three levels of 1E18 cm⁻³, 3E18 cm⁻³, and 1E19 cm⁻³.

As is seen from FIG. 17, the concentration of the n-type impurity was set higher than or equal to 3E18 cm⁻³, and thus instead of increasing the maximum electric field at the end portion of drain layer 7 on the side of gate layer 6, the maximum electric field at the end portion of gate layer 6 on the side of drain layer 7 was reduced. Consequently, depending on the depth of region 8 doped with the n-type impurity, the concentration of the n-type impurity is set higher than or equal to 3E18 cm⁻³, and thus it is possible to lower the maximum electric field at the end portion of gate layer 6 on the side of drain layer 7, with the result that it is possible to reduce the gate leakage current.

In the present variation, in addition to the effects of the embodiment and the first to fifteenth variations, it is possible to lower the maximum electric field at the end portion of gate layer 6 on the side of drain layer 7, and thus it is possible to reduce the gate leakage current.

### (Seventeenth Variation)

Then, a description will be given of a nitride semiconductor device according to a sixteenth variation of the embodiment in which the thickness of the region doped with the n-type impurity is less than or equal to 40 nm. In the present variation, the thickness of region 8 doped with the n-type impurity is less than or equal to 40 nm (see, for example, FIG. 1 and the like).

FIG. 17 shows results of an electric field simulation in the present variation. The figure shows results obtained by simulating the maximum electric field at the end portion of gate layer 6 on the side of drain layer 7 and at the end portion of drain layer 7 on the side of gate layer 6 with the assumption that the width of region 8 doped with the n-type impurity in a gate-to-drain direction was fixed at 0.5 μm, the end portion of region 8 doped with the n-type impurity on the side of gate layer 6 was located 0.5 μm from the end portion of drain layer 7 on the side of gate layer 6, a drain voltage was 650 V, a gate voltage was 0 V, and a source voltage was 0 V. The depth of region 8 doped with the n-type impurity was calculated to be three levels of 20 nm, 30 nm, and 40 nm from the surface of second nitride semiconductor layer 4, and the concentration of the impurity in region 8 doped with the n-type impurity was calculated to be three levels of 1E18 cm⁻³, 3E18 cm⁻³, and 1E19 cm⁻³. Region 8 doped with the n-type impurity is defined as a region in which the concentration of the n-type impurity is higher than or equal to 1E17 cm⁻³.

As is seen from FIG. 17, in a case where the concentration of the impurity in region 8 doped with the n-type impurity was set to 1E19 cm⁻³, when the thickness of region 8 doped with the n-type impurity was greater than or equal to 40 nm, the maximum electric field at the end portion of drain layer 7 on the side of gate layer 6 was increased to significantly exceed the maximum electric field at the end portion of gate layer 6 on the side of drain layer 7. Therefore, the possibility of dielectric breakdown at the end portion of drain layer 7 on the side of gate layer 6 is increased. Consequently, the thickness of region 8 doped with the n-type impurity is set less than or equal to 40 nm, and thus it is possible to lower the maximum electric field at the end portion of drain layer 7 on the side of gate layer 6.

In the present variation, in addition to the effects of the embodiment and the first to sixteenth variations, it is possible to lower the maximum electric field at the end portion of drain layer 7 on the side of gate layer 6, and thus voltage resistance between the gate and the drain can be ensured.

### (Manufacturing Method)

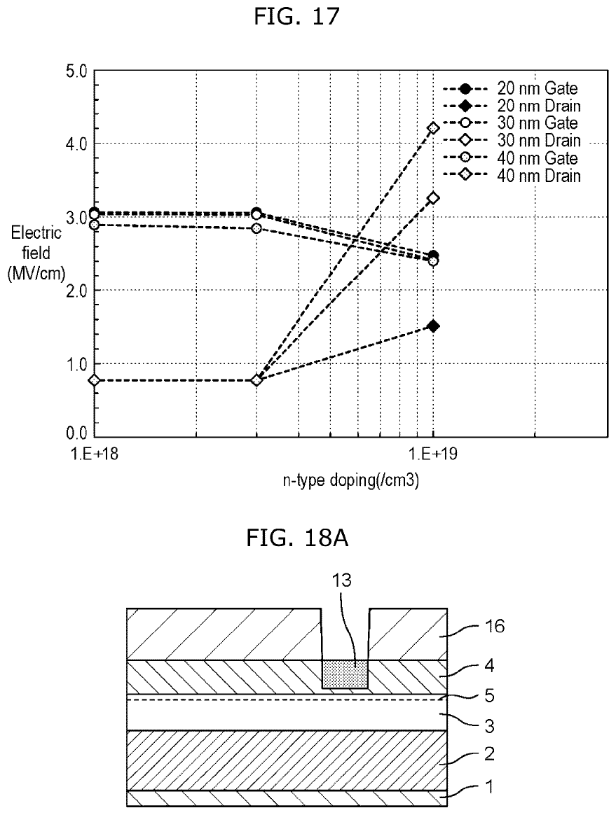

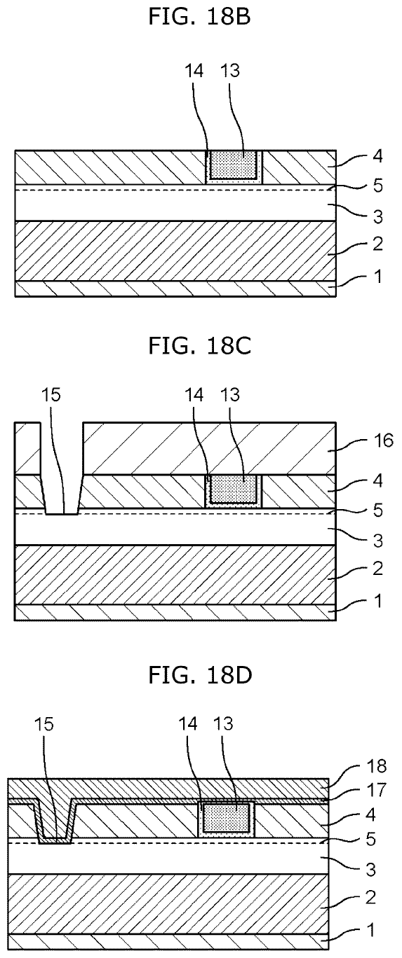

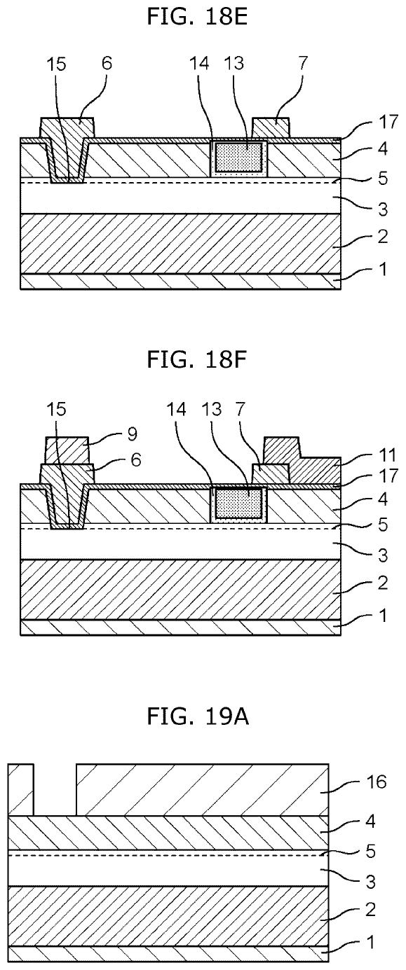

Then, FIGS. 18A to 18F show cross-sectional views of steps in a method for manufacturing a structure with omission of source electrode 10 in the structure shown in FIG. 16. The present manufacturing method describes the minimum configuration, and the present disclosure is not limited to the present manufacturing method. The present disclosure is also not limited to the order of the steps in the present manufacturing method.

On appropriate Si substrate 1 (other examples include substrates of sapphire, SiC, GaN, AlN, and the like), a known epitaxial growth technique such as an MOCVD method is used to form appropriate buffer layer 2 (for example, a single layer or a plurality of layers of Group III nitride semiconductors such as GaN, AlGaN, AIN, InGaN, InN, and AlInGaN). Then, on buffer layer 2, first nitride semiconductor layer 3 (for example, a single layer or a plurality of layers of Group III nitride semiconductors such as InGaN, InN, AlGaN, and AlInGaN) including GaN is formed. Then, on first nitride semiconductor layer 3, second nitride semiconductor layer 4 (other examples include Group III nitride semiconductors such as GaN, InGaN, AlGaN, AlN, and AlInGaN) including AlGaN is formed. Second nitride semiconductor layer 4 has a bandgap larger than that of first nitride semiconductor layer 3. When second nitride semiconductor layer 4 includes AlGaN, and first nitride semiconductor layer 3 includes GaN, a piezoelectric charge generated by a difference in lattice constant between AlGaN and GaN and a difference in bandgap can generate a high concentration of two-dimensional electron gas 5 on the side of first nitride semiconductor layer 3 in the vicinity of an interface between second nitride semiconductor layer 4 and first nitride semiconductor layer 3. In the present structure, a gate recess structure is provided later to control a threshold voltage (Vth), and thus when the Al composition of second nitride semiconductor layer 4 is greater than or equal to 15%, even if its film thickness is greater than or equal to 40 nm, a normally-off operation can be performed.

Then, resist pattern 16 is formed on second nitride semiconductor layer 4 using a known photolithography technique. Then, damaged region 13 is formed from the surface side via resist pattern 16 by ion implantation (FIG. 18A). In the ion implantation, Si (or Ge or the like) which is the n-type impurity is implanted.

In the ion implantation, the n-type impurity implanted into damaged region 13 has two purposes: one purpose of obtaining a low-resistant n-type nitride semiconductor layer; and the other purpose of reducing the electric field strength of gate layer 6 and drain layer 7, with the result that it is necessary to carefully set the concentration. Specifically, the concentration is at least higher than or equal to 1E18 cm⁻³, and preferably higher than or equal to 3E18 cm⁻³ if possible. The concentration is preferably lower than or equal to 1E21 cm⁻³ such that the ion-implanted crystal is prevented from having a completely amorphous structure due to ion implantation damage. The ion implantation conditions depend on the film thickness of an epitaxial structure used, but Si serving as the n-type impurity is implanted at an energy of 10 keV to 50 keV in the range of about 1E13 cm⁻² to 3E15 cm⁻². In this way, Si having a concentration of about 1E18 cm⁻³ to 1E21 cm⁻³ can be implanted to a depth of about 20 nm to 100 nm. At this point, the crystal lattice of damaged region 13 has collapsed due to ion implantation damage, and thus damaged region 13 has been amorphous.

Then, resist pattern 16 on second nitride semiconductor layer 4 is completely removed by a known ashing method, an organic cleaning method, sulfur-peroxide cleaning and the like, and high-temperature activation annealing is performed using a known vertical annealing furnace, a horizontal annealing furnace, a rapid thermal processing (RTA) device, or the like. The activation annealing is performed to activate the ion-implanted n-type impurity. Since the activation annealing is performed at a very high temperature, a silicon oxide film, a silicon nitride film, or the like is used as a protective film (not shown) to prevent the surface of second nitride semiconductor layer 4 from being thermally decomposed. The n-type impurity added by the ion implantation into damaged region 13 is diffused to the surrounding area by the activation annealing, and thus diffusion region 14 is formed. Then, the protective film, such as a silicon oxide film or a silicon nitride film, which is formed to prevent the surface of second nitride semiconductor layer 4 from being thermally decomposed is removed using a known hydrofluoric acid cleaning method or the like (FIG. 18B).

In order to activate the n-type impurity in the nitride semiconductor and to form diffusion region 14 around damaged region 13, the activation annealing is usually performed at 1100° C. or more, and preferably 1150° C. or more for about 1 to 30 minutes.

Diffusion region 14 is provided in all the upper, lower, left and right sides of the nitride semiconductor layer in contact with damaged region 13. When the lower end of damaged region 13 stops halfway through second nitride semiconductor layer 4 (FIG. 18A), diffusion region 14 may stop in second nitride semiconductor layer 4 (FIG. 18B), but may reach two-dimensional electron gas 5 in first nitride semiconductor layer 3 from the interior of second nitride semiconductor layer 4 (not shown).

Diffusion region 14 is defined as a region which is in contact with damaged region 13 and into which the n-type impurity is diffused from damaged region 13. Here, more specifically, diffusion region 14 is defined as a region in which the concentration of the n-type impurity is higher than or equal to 1E17 cm⁻³. Since the n-type impurity in diffusion region 14 is diffused from damaged region 13, the concentration of the n-type impurity in diffusion region 14 is necessarily lower than that in damaged region 13.

Diffusion region 14 has no or very little ion implantation damage in a downward direction and a lateral direction, and has good crystallinity among the upper, lower, left and right sides in contact with damaged region 13.

As shown in FIG. 18B, the thickness of diffusion region 14 may extend from the surface side of second nitride semiconductor layer 4 in the depth direction, and stop in second nitride semiconductor layer 4. Alternatively, as shown in FIG. 11, diffusion region 14 may reach first nitride semiconductor layer 3, but when diffusion region 14 is excessively deep, as described in the embodiment and the first to seventeenth variations, the maximum electric field at the end portion of drain layer 7 on the side of gate layer 6 is increased to significantly exceed the maximum electric field at the end portion of gate layer 6 on the side of drain layer 7. In this way, the possibility of dielectric breakdown at the end portion of drain layer 7 on the side of gate layer 6 is increased. Hence, the thickness of region 8 doped with the n-type impurity is set less than or equal to 40 nm, and thus it is possible to lower the maximum electric field at the end portion of drain layer 7 on the side of gate layer 6.

Region 8 which is doped with the n-type impurity and is shown in FIGS. 1 to 11 can be regarded as the sum of diffusion region 14 and damaged region 13 shown in FIGS. 12 to 16.

Then, resist pattern 16 is formed by a known lithography method, and gate recess 15 is formed by dry etching using an inductively coupled plasma reactive ion etching (ICP-RIE) method or the like (FIG. 18C). As shown in FIG. 18C, the bottom surface of gate recess 15 may penetrate second nitride semiconductor layer 4 to reach first nitride semiconductor layer 3, or may stop halfway through second nitride semiconductor layer 4 (not shown).

Then, resist pattern 16 is removed and cleaned using the known ashing method, the organic cleaning method, the sulfur-peroxide cleaning method, and the like, and thereafter, third nitride semiconductor layer 17 (other examples include Group III nitride semiconductors such as GaN, InGaN, AlGaN, AlN, and AlInGaN) including AlGaN is formed using the known epitaxial growth technique such as the MOCVD method. Then, on third nitride semiconductor layer 17, fourth nitride semiconductor layer 18 (other examples include group III nitride semiconductors such as p-InGaN, p-InN, p-AlGaN, and p-AlInGaN) containing the p-type impurity (such as Mg, Zn, or C) which includes p-GaN is formed by regrowth (FIG. 18D). Third nitride semiconductor layer 17 is formed to control the Vth of a field effect transistor (FET), and thus, in order to cause the FET to perform a normally-off operation, it is necessary to adjust an Al composition and a film thickness as necessary. For example, in order to set the Vth to about +1 V, it is necessary to set the Al composition of AlGaN to about 20% and to set the film thickness to about 20 nm. When third nitride semiconductor layer 17 includes a material, such as AlGaN, which contains Al, since a lateral growth rate is slow, gate recess 15 is not filled, and third nitride semiconductor layer 17 is grown along gate recess 15 as shown in FIG. 18D. By contrast, when fourth nitride semiconductor layer 18 does not include a material, such as p-GaN, which does not contain Al, since the lateral growth rate is fast, fourth nitride semiconductor layer 18 is grown to fill gate recess 15 as shown in FIG. 18D. The concentration of the p-type impurity (such as Mg, Zn or C) in fourth nitride semiconductor layer 18 is higher than or equal to 1E19 cm⁻³, and preferably higher than or equal to 5E19 cm⁻³ if possible in order to achieve p-type conversion.

In the process of forming third nitride semiconductor layer 17, trimethylgallium (TMG) and trimethylaluminum (TMA) serving as Group III raw materials, ammonia serving as a Group V raw material, and nitrogen and hydrogen serving as carrier gases are supplied from the surface side of damage region 13, and thus the crystallinity of damaged region 13 is somewhat restored, with the result that the structure of damaged region 13 becomes a slightly amorphous-like structure which is not a completely amorphous but has better crystallinity. Hence, the crystallinity of third nitride semiconductor layer 17 which is directly grown immediately above damaged region 13 whose crystallinity has been restored is improved, and thus third nitride semiconductor layer 17 is grown epitaxially.

Since the regrowth step described above is performed at a very high temperature of about 1000° C., the n-type impurity is further diffused to the surroundings, and thus diffusion region 14 further slightly spreads vertically and laterally. Here, diffusion region 14 also slightly spreads to third nitride semiconductor layer 17 which has been regrown (FIG. 18D).

Then, on fourth nitride semiconductor layer 18, a resist pattern is formed by the known lithography method (not shown), and selective dry etching using the inductively coupled plasma reactive ion etching (ICP-RIE) method or the like is performed to form gate layer 6 and drain layer 7. Even if the selective dry etching is performed, since the selectivity ratio of the dry etching rate of fourth nitride semiconductor layer 18 and third nitride semiconductor layer 17 is not infinite, third nitride semiconductor layer 17 is over-etched by several nanometers to several tens of nanometers (not shown). For example, when the regrowth thickness of third nitride semiconductor layer 17 is about 20 nm, the over-etching may be stopped halfway through third nitride semiconductor layer 17 (not shown), or third nitride semiconductor layer 17 may be over-etched by about 20 nm to completely remove third nitride semiconductor layer 17 except a part immediately below gate layer 6 (not shown). Furthermore, over-etching may be performed to completely dig down to second nitride semiconductor layer 4 (not shown).

When fourth nitride semiconductor layer 18 containing the p-type impurity (such as Mg, Zn, or C) which includes p-GaN is continuously formed after the formation of third nitride semiconductor layer 17, the p-type impurity is diffused from the surface side of third nitride semiconductor layer 17, and thus a diffusion region of the p-type impurity is generated (not shown). If the concentration of the p-type impurity in the diffusion region of the p-type impurity is so excessively high as to be 5E18 cm⁻³ or more, the diffusion region becomes a p-type nitride semiconductor layer, with the result that the diffusion region of the p-type impurity has a low resistance. In such a case, a surface leakage current when the FET or the like is formed is increased. Hence, it is desirable to use the over-etching described above to remove the diffusion region of the p-type impurity whose concentration is higher or equal to 5E18 cm⁻³ except a part immediately below gate layer 6. In other words, the concentration of the p-type impurity on the side of the outermost surface of the diffusion region of the p-type impurity except the part immediately below gate layer 6 is preferably lower than or equal to 5E18 cm⁻³.

Then, the resist pattern is removed and cleaned using the known ashing method, the organic cleaning method, the sulfur-peroxide cleaning method, and the like (FIG. 18E).

Then, the activation annealing is performed on the p-type impurity using a known annealing technique in a gas atmosphere of nitrogen or the like at 700 to 900° C. for about 10 to 60 minutes. In this way, about 1% of the p-type impurity is activated, and thus gate layer 6 and drain layer 7 are converted to p-type layers.

Then, on drain layer 7 and second nitride semiconductor layer 4, a source electrode (not shown) and drain electrode 11 are formed using the known photolithography technique, a deposition technique, a lift-off technique, a sputtering technique, a dry etching technique, an annealing (alloying) technique, the ashing method, the organic cleaning method, the sulfur-peroxide cleaning method, and the like. Drain electrode 11 includes an electrode formed of one or a combination of two or more of metals such as Ti, Al, Mo, and Hf which are in ohmic contact with the nitride semiconductor layer, and is electrically connected to two-dimensional electron gas 5. Drain electrode 11 may be electrically connected to two-dimensional electron gas 5, and may be present on first nitride semiconductor layer 3, on second nitride semiconductor layer 4, or on third nitride semiconductor layer 17.

Gate electrode 9 is finally formed using the known photolithography technique, the deposition technique, the lift-off technique, the sputtering technique, the dry etching technique, the annealing (alloying) technique, the ashing method, the organic cleaning method, the sulfur-peroxide cleaning method, and the like (FIG. 18F). Gate electrode 9 may be an electrode which is formed of one or a combination of two or more of metals such as Ti, Ni, Pd, Pt, Au, W, WSi, Ta, TiN, Al, Mo, Hf and Zr. Although gate electrode 9 may be in ohmic contact with or in Schottky contact with gate layer 6, since ohmic contact is more reliable for the gate electrode, it is desirable to use an electrode formed of one or a combination of two or more of metals such as Ni, Pt, Pd, Au, Ti, Cr, In, Sn, and Al which have low contact resistance.

An effect of the present manufacturing method will be described. The present manufacturing method is used to change the electric field strength of the end of drain layer 7 on the gate side, and thus it is possible to lower the maximum electric field strength between the gate and the drain, with the result that it is possible to manufacture a structure for reducing the gate leakage current. The concentration of two-dimensional electron gas 5 immediately below diffusion region 14 and damaged region 13 between the gate and the drain is increased, and thus sheet resistance is reduced, with the result that it is possible to reduce the on-resistance and to increase the maximum drain current.

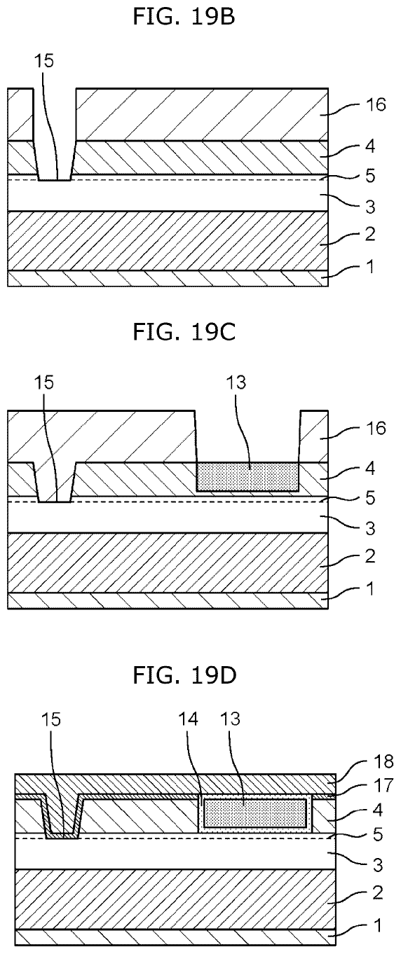

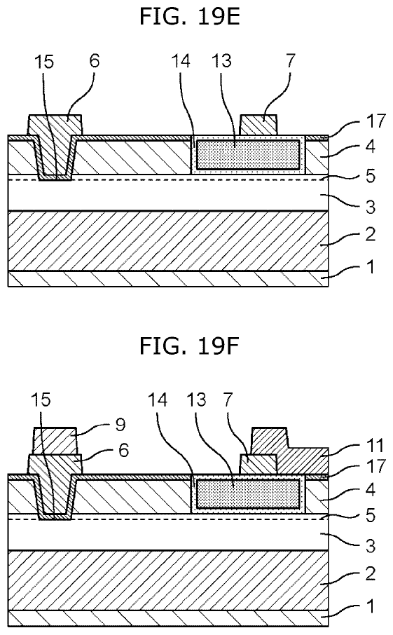

Then, FIGS. 19A to 19F are cross-sectional views showing a manufacturing method in which the activation annealing is performed at a timing different from the manufacturing method shown in FIGS. 18A to 18F in the structure shown in FIG. 16. The present manufacturing method describes the minimum configuration, and the present disclosure is not limited to the present manufacturing method. The present disclosure is also not limited to the order of the steps in the present manufacturing method.

In the present manufacturing method, a gate recess step (FIGS. 19A and 19B) and an ion implantation step (FIG. 19C) are first performed. In the order in which the gate recess step and the ion implantation step are performed, as shown in FIGS. 18A to 18C, the ion implantation step may be first performed, or as shown in FIGS. 19A to 19C, the gate recess step may be first performed. A manufacturing method in each of the steps is the same as that described in FIGS. 18A to 18C.

Then, the resist pattern and the like are completely removed by the known ashing method, the organic cleaning method, the sulfur-peroxide cleaning, and the like, and thus the surface thereof is brought into a cleaned state. Thereafter, third nitride semiconductor layer 17 (other examples include Group III nitride semiconductors such as GaN, InGaN, AlGaN, AIN, and AlInGaN) including AlGaN is formed using the known epitaxial growth technique such as the MOCVD method.

In the process of forming third nitride semiconductor layer 17, trimethylgallium (TMG) and trimethylaluminum (TMA) serving as Group III raw materials, ammonia serving as a Group V raw material, and nitrogen and hydrogen serving as carrier gases are supplied from the surface side of damage region 13, and thus the crystallinity of damaged region 13 is somewhat restored, with the result that the structure of damaged region 13 becomes a slightly amorphous-like structure which is not a completely amorphous but has better crystallinity. Hence, the crystallinity of third nitride semiconductor layer 17 which is directly grown immediately above damaged region 13 whose crystallinity has been restored is improved, and thus third nitride semiconductor layer 17 is grown epitaxially.

Then, immediately after the formation of third nitride semiconductor layer 17, the activation annealing is continuously performed on Si (or Ge or the like) serving as the n-type impurity at high temperature in a MOCVD chamber (in-situ).

In order to activate the n-type impurity in the nitride semiconductor and to form diffusion region 14 around damaged region 13, the activation annealing is usually performed at 1100° C. or more, preferably 1150° C. or more for about 1 to 30 minutes.

When the in-situ activation annealing described above is performed before the formation of third nitride semiconductor layer 17, and second nitride semiconductor layer 4 includes, for example, GaN which does not contain Al, second nitride semiconductor layer 4 at the bottom surface of gate recess 15 is etched by a carrier gas such as hydrogen and a raw material gas such as ammonia, and thus gate recess 15 is deeper. Hence, when the in-situ activation annealing is performed, it is desirable to perform the in-situ activation annealing after the formation of third nitride semiconductor layer 17.

As shown in the present manufacturing method, even when the activation annealing is performed after the formation of third nitride semiconductor layer 17 including Al which is resistant to thermal decomposition, thermal decomposition slightly occurs from the surface side of third nitride semiconductor layer 17, and thus stoichiometry is lost, and the film of third nitride semiconductor layer 17 is reduced. However, in the present manufacturing method, fourth nitride semiconductor layer 18 is formed after the activation annealing, and thus elements of groups III and V which have been released by the activation annealing can be resupplied to third nitride semiconductor layer 17, with the result that the crystallinity of third nitride semiconductor layer 17 is improved.

Even if the film of third nitride semiconductor layer 17 is reduced by the thermal decomposition of the activation annealing, additional regrowth may be performed for the reduced film (not shown). The additional nitride semiconductor layer for the reduced film has a bandgap larger than that of first nitride semiconductor layer 3, and is in direct contact with third nitride semiconductor layer 17. Since an interface with third nitride semiconductor layer 17 immediately below the additional nitride semiconductor layer for the reduced film may cause the gate leakage current when a field effect transistor is formed, it is desirable to prevent the two-dimensional electron gas from being formed. Hence, it is desirable that the band gap of the nitride semiconductor layer be equivalent to or smaller than that of second nitride semiconductor layer 4. When the nitride semiconductor layer includes, for example, AlGaN, the bandgap is equivalent to or smaller than that of third nitride semiconductor layer 17, and thus the Al composition is lowered, with the result that the crystallinity is enhanced.

Diffusion region 14 is formed in all the upper, lower, left and right sides of the nitride semiconductor layer in contact with damaged region 13. When the lower end of damaged region 13 stops halfway through second nitride semiconductor layer 4 (FIG. 19C), diffusion region 14 may stop in second nitride semiconductor layer 4 (FIG. 19D), but may reach two-dimensional electron gas 5 in first nitride semiconductor layer 3 from the interior of second nitride semiconductor layer 4 (not shown). The activation annealing is performed after the formation of third nitride semiconductor layer 17, and thus diffusion region 14 can also be spread to third nitride semiconductor layer 17 on damaged region 13.

Diffusion region 14 has no or very little ion implantation damage in a downward direction and a lateral direction, and has good crystallinity among the upper, lower, left and right sides in contact with damaged region 13.

As shown in FIG. 19D, the thickness of diffusion region 14 may extend from the surface side of second nitride semiconductor layer 4 in the depth direction, and stop in second nitride semiconductor layer 4. Alternatively, as shown in FIG. 11, diffusion region 14 may reach first nitride semiconductor layer 3, but when diffusion region 14 is excessively deep, as described in the first to seventeenth variations of the embodiment, the maximum electric field at the end portion of drain layer 7 on the side of gate layer 6 is increased to significantly exceed the maximum electric field at the end portion of gate layer 6 on the side of drain layer 7. In this way, the possibility of dielectric breakdown at the end portion of drain layer 7 on the side of gate layer 6 is increased. Hence, the thickness of region 8 doped with the n-type impurity is set less than or equal to 40 nm, and thus it is possible to lower the maximum electric field at the end portion of drain layer 7 on the side of gate layer 6.

Diffusion region 14 is defined as a region which is in contact with damaged region 13 and into which the n-type impurity is diffused from damaged region 13. Here, more specifically, diffusion region 14 is defined as a region in which the concentration of the n-type impurity is higher than or equal to 1E17 cm⁻³. Since the n-type impurity in diffusion region 14 is diffused from damaged region 13, the concentration of the n-type impurity in diffusion region 14 is necessarily lower than that in damaged region 13.

Region 8 which is doped with the n-type impurity and is shown in FIGS. 1 to 11 can be regarded as the sum of diffusion region 14 and damaged region 13 shown in FIGS. 12 to 16.

Then, immediately after the activation annealing, on third nitride semiconductor layer 17, fourth nitride semiconductor layer 18 (other examples include group III nitride semiconductors such as p-InGaN, p-InN, p-AlGaN, and p-AlInGaN) containing the p-type impurity (such as Mg, Zn, or C) which includes p-GaN is formed by regrowth (FIG. 19D). Third nitride semiconductor layer 17 is formed to control the Vth of a field effect transistor (FET), and thus, in order to cause the FET to perform a normally-off operation, it is necessary to adjust an Al composition and a film thickness as necessary. For example, in order to set the Vth to about +1 V, it is necessary to set the Al composition of AlGaN to about 20% and to set the film thickness to about 20 nm. When third nitride semiconductor layer 17 includes a material, such as AlGaN, which contains Al, since a lateral growth rate is slow, gate recess 15 is not filled, and third nitride semiconductor layer 17 is grown along gate recess 15 as shown in FIG. 19D. By contrast, when fourth nitride semiconductor layer 18 does not include a material, such as p-GaN, which does not contain Al, since the lateral growth rate is fast, fourth nitride semiconductor layer 18 is grown to fill gate recess 15 as shown in FIG. 19D. The concentration of the p-type impurity (such as Mg, Zn or C) in fourth nitride semiconductor layer 18 is higher than or equal to 1E19 cm⁻³, and preferably higher than or equal to 5E19 cm⁻³ if possible in order to achieve p-type conversion.

Since the regrowth step described above is performed at a very high temperature of about 1000° C., the n-type impurity is further diffused to the surroundings, and thus diffusion region 14 further slightly spreads vertically and laterally. Here, diffusion region 14 may also further spread from third nitride semiconductor layer 17 which has been regrown to fourth nitride semiconductor layer 18 as shown in FIG. 9.

Then, the step of selectively dry etching fourth nitride semiconductor layer 18 to form gate layer 6 and drain layer 7 (FIG. 19E), the step of performing the activation annealing on the p-type impurity, the step of forming the source electrode (not shown) and drain electrode 11, and the step of forming gate electrode 9 (FIG. 19F) are the same as those shown in FIGS. 18E and 18F.

An effect of the present manufacturing method will be described. In addition to the effect of the manufacturing method shown in FIGS. 18A to 18F, the present manufacturing method is used, and thus the activation annealing can be performed in-situ simultaneously with the regrowth step of third nitride semiconductor layer 17 and fourth nitride semiconductor layer 18, with the result that the process steps can be simplified. The activation annealing is performed after the formation of third nitride semiconductor layer 17, and thus diffusion region 14 can also be spread to third nitride semiconductor layer 17 on damaged region 13. In this way, the n-type layer can be further formed to the outermost surface of third nitride semiconductor layer 17, thus the electric field strength of the end of drain layer 7 on the gate side is more effectively changed, and therefore, it is possible to lower the maximum electric field strength between the gate and the drain, with the result that it is possible to manufacture a structure for reducing the gate leakage current.

### (Outline)

The characteristics of the nitride semiconductor device described based on the above embodiment will be described below.

A nitride semiconductor device according to a first aspect of the present disclosure includes: a substrate; a first nitride semiconductor layer disposed above the substrate; a second nitride semiconductor layer that is in contact with a top of the first nitride semiconductor layer and has a bandgap larger than a bandgap of the first nitride semiconductor layer; a gate layer that is selectively disposed on the second nitride semiconductor layer and includes a p-type nitride semiconductor; a drain layer that is spaced apart from the gate layer and includes a p-type nitride semiconductor; and a drain electrode that is electrically connected to both the second nitride semiconductor layer and the drain layer, the second nitride semiconductor layer includes a region that is doped with an n-type impurity, and an end portion of the region on a gate side is located between the gate layer and the drain layer, the region being doped with the n-type impurity.

A nitride semiconductor device according to a second aspect of the present disclosure is characterized in that in the nitride semiconductor device according to the first aspect, an end portion of the region of the second nitride semiconductor layer on a side opposite to the gate side is located between the gate layer and the drain layer, the region being doped with the n-type impurity.

A nitride semiconductor device according to a third aspect of the present disclosure is characterized in that in the nitride semiconductor device according to the first or second aspect, the region of the second nitride semiconductor layer doped with the n-type impurity is located on a side of the drain layer relative to an intermediate line of the gate layer and the drain layer.

A nitride semiconductor device according to a fourth aspect of the present disclosure is characterized in that in the nitride semiconductor device according to the first or third aspect, the region of the second nitride semiconductor layer doped with the n-type impurity is in contact with an end of the drain layer.

A nitride semiconductor device according to a fifth aspect of the present disclosure is characterized in that in the nitride semiconductor device according to at least one of the first to fourth aspects, the region of the second nitride semiconductor layer doped with the n-type impurity is in an outmost surface of the second nitride semiconductor layer.

A nitride semiconductor device according to a sixth aspect of the present disclosure is characterized in that in the nitride semiconductor device according to any one of the first and the third to fifth aspects, the region of the second nitride semiconductor layer doped with the n-type impurity is continuous with below the drain layer.

A nitride semiconductor device according to a seventh aspect of the present disclosure is characterized in that in the nitride semiconductor device according to any one of the first and the third to sixth aspects, the region of the second nitride semiconductor layer doped with the n-type impurity is also present below the drain electrode.

A nitride semiconductor device according to an eighth aspect of the present disclosure is characterized in that in the nitride semiconductor device according to any one of the first and the third to seventh aspects, the region of the second nitride semiconductor layer doped with the n-type impurity is continuous with below the drain layer and with below the drain electrode.

A nitride semiconductor device according to a ninth aspect of the present disclosure is characterized in that in the nitride semiconductor device according to any one of the first to eighth aspects, the region of the second nitride semiconductor layer doped with the n-type impurity is also present in the drain layer.

A nitride semiconductor device according to a tenth aspect of the present disclosure is characterized in that in the nitride semiconductor device according to any one of the first to ninth aspects, the region of the second nitride semiconductor layer doped with the n-type impurity is also present in a surface of the drain layer.

A nitride semiconductor device according to an eleventh aspect of the present disclosure is characterized in that in the nitride semiconductor device according to any one of the first to tenth aspects, the region of the second nitride semiconductor layer doped with the n-type impurity reaches the first nitride semiconductor layer in a depth direction.

A nitride semiconductor device according to a twelfth aspect of the present disclosure is characterized in that in the nitride semiconductor device according to any one of the first to eleventh aspects, the region of the second nitride semiconductor layer doped with the n-type impurity includes a damaged region in a center of the region and a diffusion region around the damaged region, and a concentration of the n-type impurity in the diffusion region is lower than a concentration of the n-type impurity in the damaged region.

A nitride semiconductor device according to a thirteenth aspect of the present disclosure is characterized in that in the nitride semiconductor device according to any one of the first to twelfth aspects, the region of the second nitride semiconductor layer doped with the n-type impurity includes a damaged region in a center of the region and a diffusion region around the damaged region, and the diffusion region is present below the drain layer.

A nitride semiconductor device according to a fourteenth aspect of the present disclosure is characterized in that in the nitride semiconductor device according to any one of the first to thirteenth aspects, the region of the second nitride semiconductor layer doped with the n-type impurity includes a damaged region in a center of the region and a diffusion region around the damaged region, and the damaged region is present below the drain layer.

A nitride semiconductor device according to a fifteenth aspect of the present disclosure is characterized in that in the nitride semiconductor device according to any one of the first to fourteenth aspects, the region of the second nitride semiconductor layer doped with the n-type impurity is within a range of 1 μm or less from an end portion of the drain layer on the gate side toward a side of the gate layer.

A nitride semiconductor device according to a sixteenth aspect of the present disclosure is characterized in that in the nitride semiconductor device according to any one of the first to fifteenth aspects, an end portion of the region of the second nitride semiconductor layer on a side opposite to a side of the gate layer is within a range of 1 μm or less from an end portion of the drain layer on the gate side toward the side of the gate layer, the region being doped with the n-type impurity.

A nitride semiconductor device according to a seventeenth aspect of the present disclosure is characterized in that in the nitride semiconductor device according to any one of the first to sixteenth aspects, a concentration of the n-type impurity in the region of the second nitride semiconductor layer doped with the n-type impurity is higher than or equal to 3E18 cm⁻³.

A nitride semiconductor device according to an eighteenth aspect of the present disclosure is characterized in that in the nitride semiconductor device according to any one of the first to seventeenth aspects, a thickness of the region of the second nitride semiconductor layer doped with the n-type impurity is less than or equal to 40 nm.

### (Other Embodiments)

Although the nitride semiconductor devices according to one or a plurality of aspects have been described above based on the above embodiment, the present disclosure is not limited to the embodiment. Embodiments obtained by performing various types of variations conceivably by those skilled in the art on the present embodiment and embodiments formed by combining constituent elements in different embodiments are included in the scope of the present disclosure without departing from the spirit of the present disclosure.

In the embodiments described above, various changes, replacements, addition, omission, and the like can be performed in the scope of claims or in a scope equivalent thereto.

### INDUSTRIAL APPLICABILITY

According to the present disclosure, it is possible to reduce the on-resistance of a semiconductor device, to increase the maximum drain current, and therefore to enhance the performance a power device.

### REFERENCE SIGNS LIST

1 substrate
2 buffer layer
3 first nitride semiconductor layer
4 second nitride semiconductor layer
5 two-dimensional electron gas
6 gate layer
7 drain layer
8 region doped with n-type impurity
9 gate electrode
10 source electrode
11 drain electrode
12 intermediate line
13 damaged region
14 diffusion region
15 gate recess
16 resist pattern
17 third nitride semiconductor layer
18 fourth nitride semiconductor layer

1. A nitride semiconductor device comprising:
a substrate;
a first nitride semiconductor layer disposed above the substrate;
a second nitride semiconductor layer that is in contact with a top of the first nitride semiconductor layer and has a bandgap larger than a bandgap of the first nitride semiconductor layer;
a gate layer that is selectively disposed on the second nitride semiconductor layer and includes a p-type nitride semiconductor;
a drain layer that is spaced apart from the gate layer and includes a p-type nitride semiconductor; and
a drain electrode that is electrically connected to both the second nitride semiconductor layer and the drain layer,
wherein the second nitride semiconductor layer includes a region that is doped with an n-type impurity, and
an end portion of the region on a gate side is located between the gate layer and the drain layer, the region being doped with the n-type impurity.

2. The nitride semiconductor device according to claim 1,
wherein an end portion of the region of the second nitride semiconductor layer on a side opposite to the gate side is located between the gate layer and the drain layer, the region being doped with the n-type impurity.

3. The nitride semiconductor device according to claim 1,
wherein the region of the second nitride semiconductor layer doped with the n-type impurity is located on a side of the drain layer relative to an intermediate line of the gate layer and the drain layer.

4. The nitride semiconductor device according to claim 1,
wherein the region of the second nitride semiconductor layer doped with the n-type impurity is in contact with an end of the drain layer.

5. The nitride semiconductor device according to claim 1,
wherein the region of the second nitride semiconductor layer doped with the n-type impurity is in an outmost surface of the second nitride semiconductor layer.

6. The nitride semiconductor device according to claim 1,
wherein the region of the second nitride semiconductor layer doped with the n-type impurity is continuous with below the drain layer.

7. The nitride semiconductor device according to claim 1,
wherein the region of the second nitride semiconductor layer doped with the n-type impurity is also present below the drain electrode.

8. The nitride semiconductor device according to claim 1,
wherein the region of the second nitride semiconductor layer doped with the n-type impurity is continuous with below the drain layer and with below the drain electrode.

9. The nitride semiconductor device according to claim 1,
wherein the region of the second nitride semiconductor layer doped with the n-type impurity is also present in the drain layer.

10. The nitride semiconductor device according to claim 1,
wherein the region of the second nitride semiconductor layer doped with the n-type impurity is also present in a surface of the drain layer.

11. The nitride semiconductor device according to claim 1,
wherein the region of the second nitride semiconductor layer doped with the n-type impurity reaches the first nitride semiconductor layer in a depth direction.

12. The nitride semiconductor device according to claim 1,
wherein the region of the second nitride semiconductor layer doped with the n-type impurity includes a damaged region in a center of the region and a diffusion region around the damaged region, and
a concentration of the n-type impurity in the diffusion region is lower than a concentration of the n-type impurity in the damaged region.

13. The nitride semiconductor device according to claim 1,
wherein the region of the second nitride semiconductor layer doped with the n-type impurity includes a damaged region in a center of the region and a diffusion region around the damaged region, and
the diffusion region is present below the drain layer.

14. The nitride semiconductor device according to claim 1,
wherein the region of the second nitride semiconductor layer doped with the n-type impurity includes a damaged region in a center of the region and a diffusion region around the damaged region, and
the damaged region is present below the drain layer.

15. The nitride semiconductor device according to claim 1,
wherein the region of the second nitride semiconductor layer doped with the n-type impurity is within a range of 1 μm or less from an end portion of the drain layer on the gate side toward a side of the gate layer.

16. The nitride semiconductor device according to claim 1,
wherein an end portion of the region of the second nitride semiconductor layer on a side opposite to a side of the gate layer is within a range of 1 μm or less from an end portion of the drain layer on the gate side toward the side of the gate layer, the region being doped with the n-type impurity.

17. The nitride semiconductor device according to claim 1, wherein a concentration of the n-type impurity in the region of the second nitride semiconductor layer doped with the n-type impurity is higher than or equal to 3E18 cm⁻³.

18. The nitride semiconductor device according to claim 1, wherein a thickness of the region of the second nitride semiconductor layer doped with the n-type impurity is less than or equal to 40 nm.
